(19) United States
(12) Patent Application Publication
(10) Pub. No.: US 2025/0364989 A1
(43) Pub. Date: Nov. 27, 2025

(54) BIPOLAR JUNCTION DEVICES, AND METHODS AND SWITCHES USING SAME

(71) Applicant: IDEAL POWER INC., Austin, TX (US)

(72) Inventors: Mudit KHANNA, Austin, TX (US); Jiankang BU, Austin, TX (US); Ruiyang YU, Austin, TX (US); R. Daniel BRDAR, Driftwood, TX (US)

(73) Assignee: IDEAL POWER INC., Austin, TX (US)

(21) Appl. No.: 19/188,394

(22) Filed: Apr. 24, 2025

Related U.S. Application Data
(60) Provisional application No. 63/650,652, filed on May 22, 2024.

(51) Int. Cl. H03K 17/60; H03K 17/567; H10D 10/40

(52) U.S. Cl. CPC H03K 17/60; H03K 17/567; H10D 10/40

(57) ABSTRACT

Bipolar junction devices, and methods and switches using same. At least one example is a bipolar junction device that includes a lower collector-emitter defined by a lower N-type region disposed within a substrate of N-type material, a lower base defined by a lower P-type region disposed within the substrate, and an upper collector-emitter. The upper collector-emitter includes an upper P-type region disposed within the substrate and a metal layer disposed on an upper surface of the substrate. A first portion of the metal layer is electrically coupled to the upper P-type region and a second portion of the metal layer is electrically coupled to the substrate. The second portion is displaced from the first portion.

### CROSS-REFERENCE TO RELATED APPLICATIONS

This application claims the benefit of U.S. Provisional Application No. 63/650,652, filed on May 22, 2024. The entire disclosure of the application referenced above is incorporated herein by reference.

### FIELD

The present disclosure relates to bipolar junction devices, methods, and switches.

### BACKGROUND

Many electrical systems use high voltages and currents. Such electrical systems may be employed in a variety of applications ranging from electric vehicles to consumer appliances. For example, in some electric vehicles, voltages of about 1200 Volts may be selectively coupled to the electric motor(s) to propel the vehicle. To accomplish the selective coupling, electrically controlled switches may be employed. In response to an assertion of a switch signal, an electrically controlled switch couples a power source to a load circuit. Oppositely, responsive to de-assertion of the switch signal, the electrically controlled switch decouples the load from the power source.

### SUMMARY

Aspects of the present disclosure include bipolar junction devices, and methods and switches using same. At least one example is a bipolar junction device that includes a lower collector-emitter defined by a lower N-type region disposed within a substrate of N-type material, a lower base defined by a lower P-type region disposed within the substrate, and an upper collector-emitter. The upper collector-emitter includes an upper P-type region disposed within the substrate and a metal layer disposed on an upper surface of the substrate. A first portion of the metal layer is electrically coupled to the upper P-type region, a second portion of the metal layer is electrically coupled to the substrate, and the second portion is displaced from the first portion.

In other features, the second portion of the metal layer is in ohmic contact with the substrate. The first portion of the metal layer is in ohmic contact with the upper P-type region. The upper P-type region intersects the upper surface. The upper P-type region does not intersect the upper surface. The bipolar junction further includes an upper N-type region electrically disposed between the second portion of the metal layer and the substrate, and the upper N-type region intersects the upper surface. The bipolar junction device further includes an upper N-type region electrically disposed between the second portion of the metal layer and the substrate, and the upper N-type region does not intersect the upper surface.

In other features, the lower P-type region intersects a lower surface of the substrate. The lower P-type region does not intersect a lower surface of the substrate. The lower N-type region intersects a lower surface of the substrate. The lower N-type region does not intersect a lower surface of the substrate. The bipolar junction device further includes an upper component that defines the upper P-type region and a backside and a lower component that defines the lower P-type region, the lower N-type region, and a backside. The backsides of the upper component and the lower component are bonded together.

A switch assembly includes an upper terminal, a lower terminal, and a control terminal, a cascode FET defining a drain, a source coupled to the lower terminal, and a gate, a driver coupled to the gate of the cascode FET, and a bipolar junction device. The bipolar junction device includes a lower collector-emitter defined by a lower N-type region disposed within a substrate of N-type material, the lower collector-emitter coupled to the drain of the cascode FET, a lower base defined by a lower P-type region disposed within the substrate, and an upper collector-emitter coupled to the upper terminal. The upper collector-emitter includes an upper P-type region disposed within the substrate and a metal layer disposed on an upper surface of the substrate, a first portion of the metal layer electrically coupled to the upper P-type region, and a second portion of the metal layer electrically coupled to the substrate, the second portion displaced from the first portion. The driver is configured to, during periods of time when the switch assembly is forward biased and the control terminal is asserted, arrange the bipolar junction device to conduct a forward current from the upper terminal, through the upper collector-emitter, and to the lower terminal; during periods of time when the switch assembly is forward biased and the control terminal is de-asserted, arrange the bipolar junction device to block current from the upper terminal to the lower terminal, and during periods of time when the switch assembly is reversed biased, arrange the bipolar junction device to non-selectively conduct a reverse current from the lower terminal, to the lower collector-emitter, and to the upper terminal.

In other features, the driver further includes a lower FET defining a drain coupled to the lower base, a source coupled to the lower terminal, and a gate coupled to the driver. The driver is configured to, during periods of time when the switch assembly is forward biased and the control terminal is de-asserted, couple the lower base to the lower terminal by way of the lower FET and make the cascode FET non-conductive. The switch assembly further includes a source defining a positive terminal and a negative terminal and the driver is configured to, during periods of time when the switch assembly is forward biased and the control terminal is asserted, couple the positive terminal of the source to the lower base and couple the negative terminal to the lower terminal of the switch assembly and make the cascode FET conductive.

In other features, the driver further includes a source defining a positive terminal and a negative terminal and the driver is configured to, during at least portions of periods of time when the switch assembly is forward biased and the control terminal is de-asserted, couple the positive terminal of the source to the lower collector-emitter and couple the negative terminal to the lower base and make the cascode FET non-conductive. The driver is further configured to, during at least portions of periods of time when the switch assembly is reversed biased, make the cascode FET conductive. The driver further includes a lower FET defining a drain coupled to the lower base, a source coupled to the lower terminal, and a gate coupled to the driver. The driver is further configured to, during at least portions of periods of time when the switch assembly is reversed biased, make the cascode FET conductive.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

For a detailed description of example embodiments, reference will now be made to the accompanying drawings in which:

FIG. 1 shows a switch assembly in accordance with at least some embodiments;

FIG. 2 shows a bidirectional switch in accordance with at least some embodiments;

FIGS. 3A-3H show a double-sided double-base bipolar junction transistor of PNP construction in shorthand form, with example external electrical connections, to illustrate several operational states;

FIG. 4 shows a partial block diagram, partial electrical schematic, of a switch assembly 100 in accordance with at least some embodiments;

FIG. 5 shows a partial cross-sectional view of an example bipolar junction device of modular construction, in accordance with at least some embodiments;

FIG. 6 shows, in shorthand form, a partial cross-sectional view of an example bipolar junction device of modular construction, in accordance with at least some embodiments; and

FIG. 7 shows a cross-sectional view of a portion of a bipolar junction device 200 in accordance some embodiments.

### DEFINITIONS

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or a direct connection. Thus, if a first device couples to a second device, that connection may be through a direct connection or through an indirect connection via other devices and connections.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate that the recited referent may be plural.

“About” in reference to a recited parameter shall mean the recited parameter plus or minus ten percent (+/−10%) of the recited parameter.

“Assert” shall mean creating or maintaining a first predetermined state of a Boolean signal. Boolean signals may be asserted high or with a higher voltage, and Boolean signals may be asserted low or with a lower voltage, at the discretion of the circuit designer. Similarly, “de-assert” shall mean creating or maintaining a second predetermined state of the Boolean, opposite the asserted state.

“FET” shall mean a field effect transistor, such as a junction-gate FET (| FET) or metal-oxide-silicon FET (MOSFET).

“Closing” in reference to an electrically controlled switch (e.g., a FET) shall mean making the electrically controlled switch conductive. For example, closing a FET used as an electrically controlled switch may mean driving the FET to the fully conductive state.

“Opening” in reference to an electrically controlled switch (e.g., a FET) shall mean making the electrically controlled switch non-conductive. Leakage current shall not negate the status of an electrically controlled switch being non-conductive.

“Collector-emitter” of a bipolar junction device shall mean a region of the bipolar junction device through which main load current flows. For purposes of this specification and claims, the designation as a collector-emitter is independent of the underlying device physics within the bipolar junction device. For example, for PNP type devices, main load current may flow from an upper P-type region, through the bulk N-type drift region, and then out the lower P-type region, and when so used the upper P-type region and the lower P-type region are considered collector-emitters. However, in other cases, such as described in co-pending and commonly assigned U.S. application Ser. No. 18/483,939 filed Oct. 10, 2023 and titled “Methods and Systems of Operating a PNP Bi-Directional Double-Base Bipolar Junction Transistor,” the main load current may flow from an upper N-type region, through the bulk N-type drift region, and then through the lower N-type region, and when so used the upper and lower N-type regions are considered collector-emitters.

“Base” of a bipolar junction device shall mean a region of the bipolar junction device through which control current flows, the control current distinct from the main load current. For purposes of this specification and claims, the designation as a base is independent of the underlying device physics within the bipolar junction device. For example, for PNP devices, the control current may flow into an upper N-type region or a lower N-type region, and when so used the upper N-type region and the lower N-type region are considered bases. However, in other cases, such as described in co-pending and commonly assigned U.S. application Ser. No. 18/483,939 noted above, the control current may flow into a lower P-type region, and when so used the lower P-type region is considered a base.

“Upper” in reference to component (e.g., upper collector-emitter) shall not be read to imply a location of the recited component with respect to gravity. Upper may be derived from location of the device in an example drawing.

“Lower” in reference to a component (e.g., lower collector-emitter, lower base) shall not be read to imply a location of the recited component with respect to gravity. Lower may be derived from location of the device in an example drawing.

The terms “input” and “output” when used as nouns refer to connections (e.g., electrical, software), and shall not be read as verbs requiring action. For example, a timer circuit may define a clock output. The example timer circuit may create or drive a clock signal on the clock output. In systems implemented directly in hardware (e.g., on a semiconductor substrate), these “inputs” and “outputs” define electrical connections. In systems implemented in software, these “inputs” and “outputs” define parameters read by or written by, respectively, the instructions implementing the function.

“Ohmic contact” shall mean a non-rectifying electrical junction between two materials (e.g., a metal and a semiconductor).

“Controller” shall mean, alone or in combination, individual circuit components, an application specific integrated circuit (ASIC), a microcontroller with controlling software, a reduced-instruction-set computing (RISC) with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Various examples are directed to methods and systems of a double-sided bipolar junction device, hereafter just bipolar junction device. Some examples are directed to a switch assembly comprising a bipolar junction device. The example switch assembly selectively controls or conducts current through the bipolar junction device when the switch assembly is forward biased, and the switch assembly non-selectively conducts current through the bipolar junction device when the switch assembly is reverse biased. The switch assembly operated in accordance with various examples is “unidirectional,” in context meaning the switch assembly implements selective unidirectional blocking (e.g., when forward biased) and bidirectional conduction. The specification turns to an example switch assembly to orient the reader.

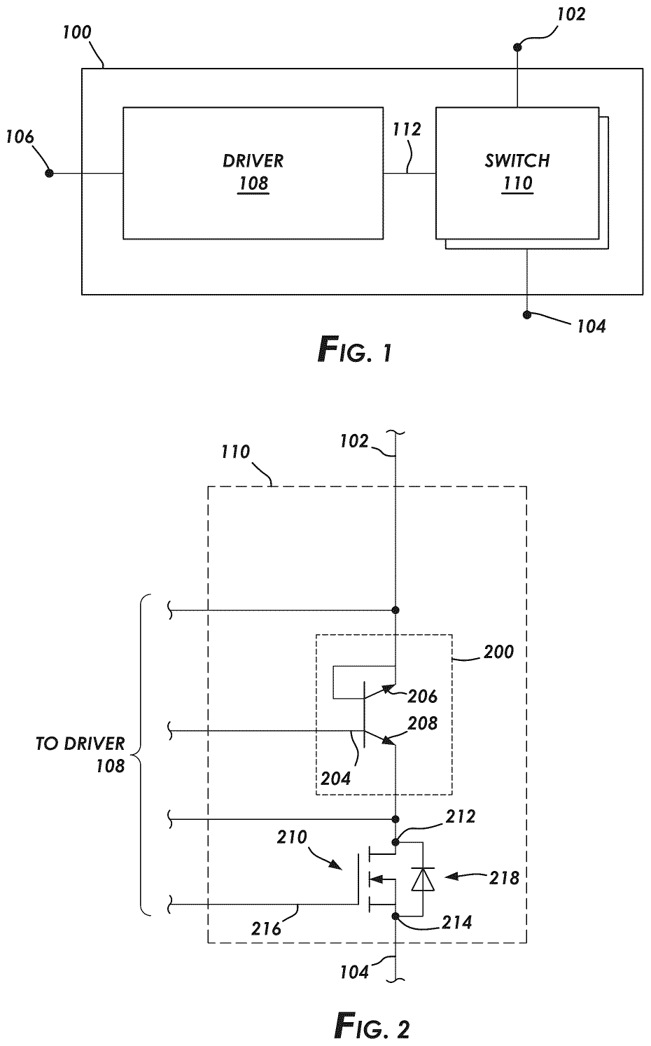

FIG. 1 shows, in block diagram form, an example switch assembly 100. In particular, the example switch assembly 100 defines an upper terminal 102, a lower terminal 104, and a control input or control terminal 106. Internally, the example switch assembly 100 includes a driver 108 and a switch 110. The driver 108 defines the control terminal 106, and the driver 108 is coupled to the switch 110, as shown by connections 112. As discussed in greater detail below, the connections 112, though shown as a single connection, represents a plurality of electrical connections to the switch 110 whose conductive state may vary. The driver 108 controls the conductive state of the switch 110 by arranging the conductive state, voltages, and/or currents on the connections 112.

One example of the switch assembly 100 may include a single switch 110. Another example switch assembly 100 may have two or more switches 110, as illustrated in FIG. 1 by the “stacked” arrangement for the switch 110. When multiple switches 110 are present, the switches 110 are electrically connected in parallel to share the load current (forward or reverse). So as not to unduly complicate the specification, the discussion that follows assumes a single switch 110. However, one having ordinary skill, and with the benefit of this disclosure, understands that the multiple switches 110 may be present depending on the designed current carrying capability of any specific switch assembly 100.

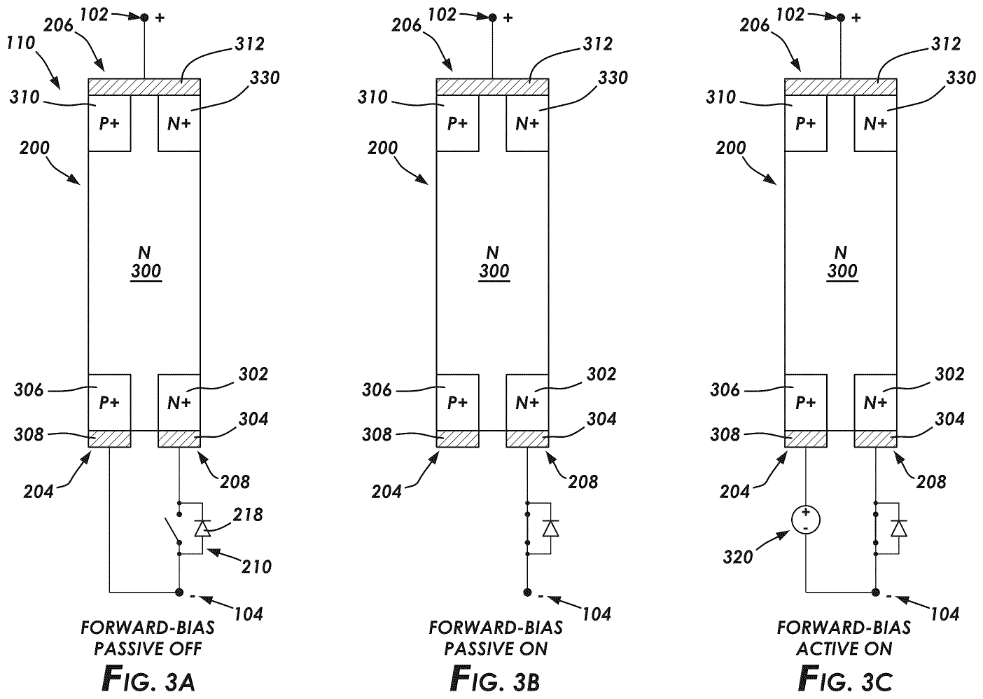

FIG. 2 shows a schematic of an example switch 110. In particular, the example switch 110 comprises a bipolar junction device 200. The example circuit symbol for the bipolar junction device 200 is coined herein and is akin to an NPN device symbol to account for the naming convention of the connections to the device; however, the NPN-like circuit symbol shall not be read to require an NPN-device. The example bipolar junction device 200 defines a lower base 204, an upper collector-emitter 206, and a lower collector-emitter 208. The example switch 110 further includes lower-main or cascode FET 210 that defines a drain 212 coupled to the lower collector-emitter 208, a source 214 coupled to the lower terminal 104, a gate 216 coupled to the driver 108, and a body diode 218. In the example, the upper collector-emitter 206 is coupled to and/or defines the upper terminal 102, and the source of the cascode FET 210 is coupled to and/or defines the lower terminal 104.

The driver 108 is coupled to the switch 110 by a plurality of electrical connections. In the example of FIG. 2, the electrical connections to the driver 108 may comprise connections to: the upper collector-emitter 206; the lower base 204; the lower collector-emitter 208; and the gate 216 of the lower cascode FET 210. In order to describe when each of these connections to the driver 108 may be utilized or active, the specification turns to example operation of the bipolar junction device 200 and cascode FET 210.

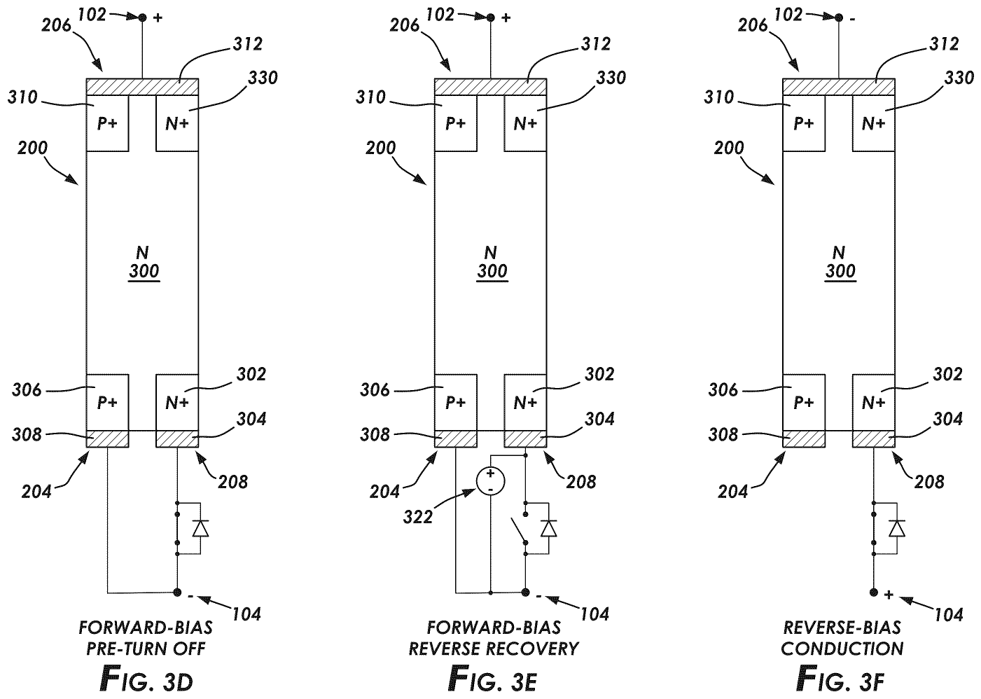

FIGS. 3A-3H show the switch 110 including the lower cascode FET 210 and a partial cross-sectional view of an example bipolar junction device 200. In order to aid in understanding, the cascode FET 210 is shown as single pole, single throw switch along with the body diode 218. When the cascode FET 210 is conductive, the single pole, single throw switch is shown as closed or conductive, and when the cascode FET 210 is non-conductive, the single pole, single throw switch is shown as open or non-conductive. Note that, even though the cascode FET 210 may be non-conductive, the body diode of the cascode FET may be conductive depending on the polarity of the applied voltage.

The example bipolar junction device 200 in each of FIGS. 3A-3H is shown as partial cross-sectional view of a device of PNP construction. Referring to FIG. 3A as representative, the example bipolar junction device 200 comprises a substrate 300 of N-type material (e.g., N⁻). The substrate 300 of N-type material defines a drift region within the bipolar junction device 200. The bipolar junction device 200 further includes the lower collector-emitter 208 defined by a lower N-type region 302 (e.g., N+) disposed within the substrate 300 and a metal layer 304. The lower collector-emitter 208 is coupled to the drain of the cascode FET 210. The bipolar junction device 200 further includes the lower base 204 defined by a lower P-type region 306 (e.g., P+) disposed within the substrate 300 and a metal layer 308. In practice, the lower P-type region 306 may be a trench of oblong shape surrounding the lower N-type region 302. While the metal layers 304 and 308 may be deposited at the same time during fabrication, an etch step electrically isolates the portion that forms the metal layer 304 from the portion that forms metal layer 308.

The example bipolar junction device 200 further includes an upper collector-emitter 206 coupled to the upper terminal 102. The upper collector-emitter 206 comprises an upper P-type region 310 (e.g., P+) disposed within the substrate 300, an upper N-type region 330 (e.g., N+) disposed within the substrate, and an upper metal layer or just upper metal 312 disposed on an upper surface of the substrate 300. In practice, the upper P-type region 310 may be a trench of oblong shape surrounding the upper N-type region 330. The upper metal 312 is electrically coupled to the upper N-type region 330 and the upper P-type region 310. That is, a first portion of the upper metal 312 is electrically coupled to the upper P-type region 310, a second portion of the upper metal 312 is coupled to the upper N-type region 330, and the first portion and second portions are spaced apart from each other. In one example, the upper metal 312 is in ohmic contact with both the upper N-type region 330 and the upper P-type region 310. In particular, the upper N-type region 330 may be used to create an ohmic contact, possibly in combination with an additional metal layer (e.g., titanium) between the metal 312 and the upper N-type region 330. A Schottky contact between the upper metal 312 and the upper P-type region 310 is also contemplated.

In example embodiments, both the top and bottom doping regions of the bipolar junction device 200 are symmetrical. That is, the upper P-type region 310 (and other upper P-type regions not shown) may be created using a reticle for selective exposure of photoresist to create a mask for doping. The lower P-type region 306 may be created using the same reticle. Similarly, the upper N-type region 330 (and other upper N-type regions not shown) may be created using a reticle for selective exposure of photoresist to create a mask for doping. The lower N-type region 302 may be created using the same reticle as used for creating the upper N-type regions. The upper doping steps take place at a different stage in the manufacture of the device than the lower doping steps, and thus the upper and lower doping regions are not necessarily fully symmetrical, but may be symmetrical to within manufacturing tolerances. In example cases, the bipolar junction device 200 is designed for 1200V service, and to provide voltage and current blocking at 1200V, the bipolar junction device 200 may have a thickness, measured from the top or upper surface to bottom or lower surface, of about 160 to 280 microns.

FIGS. 3A-3H show eight example states of the switch assembly 100 arranged for the main load current to be carried across or through the collector-emitters. The eight states may be conceptually divided into states associated with a forward bias of the bipolar junction device 200, and states associate with a reverse bias of the bipolar junction device 200. In the examples of FIGS. 3A-3E, the switch assembly 100 is forward biased, such as having the more positive polarity associated with the upper terminal 102 relative to the lower terminal 104. In the examples of FIGS. 3F-3H, the switch assembly 100 is reverse biased, such as having the more positive polarity associated with the lower terminal 104 relative to the upper terminal 102. More precisely, the example forward biased states include: passive off (FIG. 3A); passive on (FIG. 3B); active on (FIG. 3C); pre-turn off (FIG. 3D); and reverse recovery (FIG. 3E). The example reverse biased states include: conduction (FIG. 3F); an alternative conduction (FIG. 3G); and an active-on conduction (FIG. 3H). Each is addressed in turn.

FIG. 3A shows a forward biased passive-off arrangement of the example bipolar junction device 200. In particular, in the example forward biased passive-off arrangement the lower base 204 is coupled to the lower terminal 104 by the driver 108. The lower collector-emitter 208 is electrically floated, such as by the cascode FET 210 being open and its body diode 218 being non-conductive because of the applied voltage. In the arrangement of FIG. 3A, no appreciable current flows through the bipolar junction device 200 because of the blocking performed by the PN junction formed between the lower base 204 and the drift region within the substrate 300. The state of FIG. 3A is referred as “passive off” because the electrical arrangement can be implemented with purely passive components (e.g., diodes and resistors), and thus the driver 108 need not have operational power to implement the arrangement of FIG. 3A. In the passive-off arrangement, the bipolar junction device 200 blocks voltage and current, and thus the non-conductive cascode FET 210 may experience a relatively small drain-to-source voltage of about 30V or less for 1200V applied across the upper terminal 102 and lower terminal 104.

FIG. 3B shows a passive-on arrangement of the example bipolar junction device 200. In particular, the lower base 204 is electrically floated by the driver 108. The lower collector-emitter 208 is coupled to the lower terminal 104 through the cascode FET 210. Main load current thus flows from the upper terminal 102 to the upper metal 312 of the upper collector-emitter 206, through the bipolar junction device 200, then through the cascode FET 210, and then to the lower terminal 104.

Internally, the main load current divides or splits. A first portion of the main load current flows from the upper metal 312, into the upper N-type region 330, and then through the drift region of the substrate 300. A second portion of the main load current flows from the upper metal 312 into the upper P-type region 310. The portion of the main load current that flows into the upper P-type region 310 results in the injection of charge carriers into the drift region. In particular, the initial voltage drop across the bipolar junction device 200 in the arrangement of FIG. 3B is based on the substrate resistance (e.g., for a 160 micron thick substrate, about 2 ohms). As the main load current ramps upward, the PN junction formed between the upper P-type region 310 and the substrate 300 is forward biased, and thus the second portion of the main load current flows into the upper P-type region. Because of the injection of charge carriers through the upper P-type region 310, the voltage drop across the collector-emitters, Vceon, will be lower than the product of the amplitude of the main load current and the substrate resistance. In one example, the expected Vceon may be between and including 0.8 and 1.4V for 30 A of main load current. The upper collector-emitter 206, including the upper P-type region 310 and the upper N-type region 330, may be considered a merged PN resistor.

FIG. 3C shows an active-on arrangement of the example bipolar junction device 200, still with the switch assembly 100 forward biased. In particular, the upper collector-emitter 206 is coupled to the upper terminal 102. The lower collector-emitter 208 is coupled to the lower terminal 104 through the lower cascode FET 210. A source 320 (e.g., voltage source, current source) of the driver 108 provides a positive bias to the lower base 204 relative to the lower collector-emitter 208. The source 320 may provide any suitable bias current or voltage (e.g., 0.2V to 2V). The source 320 causes the injection of charge carriers across the PN junction into the drift region of the substrate 300, which further lowers the forward voltage drop Vceon. In one example, the forward voltage drop Vceon may be reduced to about 0.2V for 30 A of main load current, well below the expected forward voltage drop taking into account the substrate inherent resistance of about 2 ohms. In one example, the expected forward voltage drop Vceon may be between and including 0.2 and 0.8V for 30 A of main load current.

FIG. 3D shows a pre-turnoff arrangement of the example bipolar junction device 200. In particular, the lower collector-emitter 208 is coupled to the lower terminal 104 through the cascode FET 210. The lower base 204 is coupled, by the driver 108, to the lower terminal 104. In the pre-turnoff arrangement of FIG. 3D, charge carrier density within the drift region is reduced by the connection of the lower base 204 to the lower terminal 104, compared to, for example, the active-on arrangement of FIG. 3C. In one example, the expected forward voltage drop Vceon may be between and including 0.8V at the initiation of the arrangement of FIG. 3D, and as charge carriers are drained through the lower P-type region 306, rising to 60V for 30 amps of main load current (e.g., the product of 30A of current and the inherent resistance of about 2 Ohms).

FIG. 3E shows a reverse recovery arrangement of the example bipolar junction device 200. In particular, the lower base 204 is coupled, by the driver 108, to the lower terminal 104. The lower collector-emitter 208 is coupled to the lower terminal 104 by way of a source 322 (e.g., voltage source, current source) of the driver 108. The reverse recovery arrangement of FIG. 3E may be used to shorten the diode reverse recovery time of the PN junction formed between the lower P-type region 306 and the drift region of the substrate 300 after a period of conduction from the upper collector-emitter 206 to the lower collector-emitter 208. That is, the positive voltage between lower collector-emitter 208 and the lower base 204 pinches off the PN junction formed between the lower collector-emitter 208 and the lower base 204, to reduce reverse recovery current between the upper collector-emitter 206 and the lower base 204. Stated otherwise, in the passive-on or active-on arrangements of FIG. 3B or 3C, excess charge carriers are injected into the drift region to lower the forward voltage drop Vceon; however, in the transition from the passive- or active-on arrangements to the passive-off arrangement of FIG. 3A, the excess charge carriers result in undesirable reverse recovery current (IRR) through the lower base 204, and corresponding increase the reverse recovery time (TRR). Implementing the reverse recovery arrangement of FIG. 3E for a non-zero predetermined period of time reduces the reverse recovery current IRR and thus the reverse recovery time TRR, compared to implementations that do not implement such a reverse recovery step.

Turning now to reverse biased arrangements. FIG. 3F shows a reverse biased conduction arrangement of the example bipolar junction device 200. In particular, the lower base 204 is electrically floated by the driver 108. The lower collector-emitter 208 is coupled to the lower terminal 104 by way of the cascode FET 210 and/or the body diode 218. In the arrangement of FIG. 3F, with the applied voltage being higher on the lower terminal 104 relative to the upper terminal 102, a reverse current flows from the lower terminal 104, through the bipolar junction device 200, then to the upper terminal 102. Here again, the voltage drop across the bipolar junction device 200 is based on the inherent resistance of the substrate 300 (e.g., about 2 ohms). The voltage drop can be reduced, however.

FIG. 3G shows an alternative reverse biased conduction arrangement of the example bipolar junction device 200. In particular, the lower base 204 is electrically coupled to the lower terminal 104 by way of the driver 108. The lower collector-emitter 208 is coupled to the lower terminal 104 by way of the cascode FET 210. In the arrangement of FIG. 3G, with the applied voltage being higher on the lower terminal 104 relative to the upper terminal 102, again the reverse current flows from the lower terminal 104, through the bipolar junction device 200, then to the upper terminal 102.

In the arrangement of FIG. 3G, the reverse current divides or splits. A first portion of the reverse current flows from the lower collector-emitter 208 into the drift region of the substrate 300. A second portion of the reverse current flows into the lower base 204, which second portion results in the injection of charge carriers into the drift region. In particular, the initial voltage drop across the bipolar junction device 200 in the arrangement of FIG. 3G is based on the substrate resistance. As the reverse current ramps upward, the PN junction formed between the lower P-type region 306 and the substrate 300 becomes forward biased, and thus the second portion of the reverse current flows into the lower P-type region 306. Because of the injection of charge carriers through the lower P-type region 306, the voltage drop across the collector-emitters will be lower than the product of the amplitude of the reverse current and the substrate resistance.

FIG. 3H shows an alternative reverse biased conduction arrangement, referred to as an active-on arrangement of the example bipolar junction device 200, still with the switch assembly 100 reverse biased. In particular, the upper collector-emitter 206 is coupled to the upper terminal 102. The lower collector-emitter 208 is coupled to the lower terminal 104 through the lower cascode FET 210. The source 320 of the driver 108 provides a positive bias to the lower base 204 relative to the lower collector-emitter 208. The source 320 causes the injection of charge carriers across the PN junction into the drift region of the substrate 300, the injection greater than the injection that takes place in FIG. 3G. In one example, the voltage drop across the collector-emitters may be reduced to about 0.2V for 30 A of main load current.

With respect to transitions of the switch assembly 100 from non-conductive to conductive during forward bias, the example bipolar junction device 200 may be arranged to transition from the passive-off arrangement of FIG. 3A directly to the active-on arrangement of FIG. 3C without implementing an intermediate arrangement or state. Nevertheless, the passive-on arrangement of FIG. 3B may find use as an intermediate arrangement or state between passive off and active on.

With the respect to transitions of the switch assembly 100 from conductive to non-conductive during forward bias, in some examples the bipolar junction device 200 may be transitioned from the active-on arrangement of FIG. 3C directly to the passive-off arrangement of FIG. 3A without implementing an intermediate arrangement or state. For example, when the bipolar junction device 200 is made non-conductive during a zero current event through the switch assembly 100, the bipolar junction device 200 may transition directly to the passive-off arrangement. Nevertheless, the pre-turn off arrangement of FIG. 3D or the reverse recovery arrangement of FIG. 3E may find use as an intermediate arrangement or state in some cases, such as when a request to transition to the non-conductive state occurs during non-zero forward current flow through the bipolar junction device 200. When the reverse recovery arrangement of FIG. 3E is used, the reverse recovery may be implemented for between and including 200 and 500 nanoseconds, and in a particular case, about 400 nanoseconds.

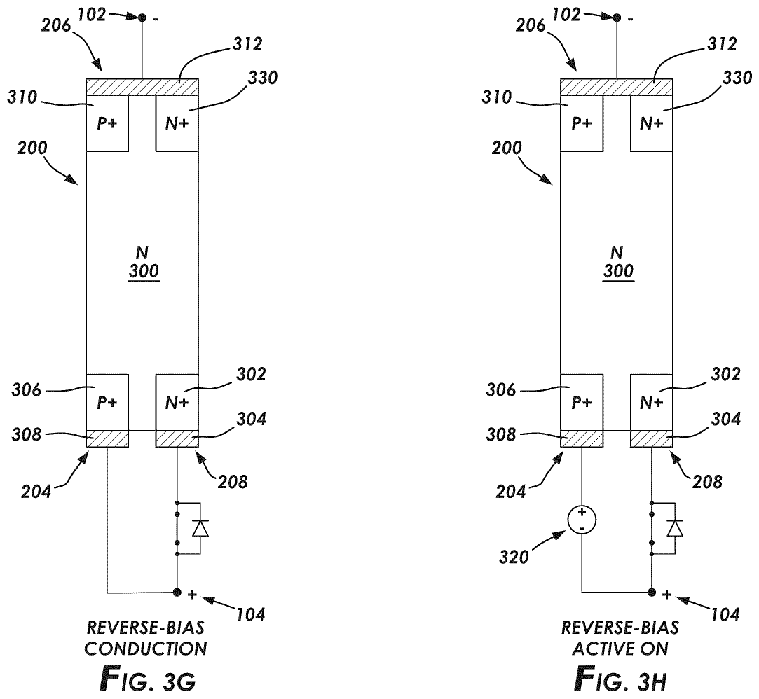

FIG. 4 shows a partial block diagram, partial electrical schematic, of an example switch assembly 100. In particular, the example switch assembly 100 comprises the example bipolar junction device 200, the cascode FET 210, and the driver 108. The circuit symbol for the bipolar junction device 200 includes the lower base 204, the upper collector-emitter 206, and the lower collector-emitter 208. The lower cascode FET 210 is shown as a single-pole, single-throw switch. Thus, when the lower cascode FET 210 is conductive, such as by assertion of its gate, the lower terminal 104 is coupled to the lower collector-emitter 208. The example driver 108 defines an upper sense terminal 408 coupled to the upper terminal 102 and upper collector-emitter 206, a lower sense terminal 410 coupled to the lower terminal 104, a lower CE terminal 412 coupled to the lower collector-emitter 208, and a lower-conduction terminal 414 coupled to the lower base 204.

The example driver 108 comprises a controller 416, an electrical isolator 418, and an isolation transformer 420. In order to place the bipolar junction device 200 in the various conduction and non-conduction modes, the example driver 108 includes a plurality of electrically controlled switches and sources of charge carriers. In particular, the example driver 108 comprises a switch 432 that has a first lead coupled to the lower terminal 104, a second lead coupled to the lower base 204, and a control input coupled to the controller 416. The example switch 432 is shown as a single-pole, single-throw switch, but in practice, the switch 432 may be a FET with the control input being a gate of the FET. Thus, when the switch 432 is made conductive by assertion of its control input, the lower base 204 is coupled to the lower terminal 104.

The driver 108 further comprises the source 320 illustratively shown as a battery. The source 320 has a negative lead coupled to the lower terminal 104. Another electrically-controlled switch 436 (hereafter just switch 436) has a first lead coupled to the positive terminal of the source 320, a second lead coupled to the lower base 204, and a control input coupled to the controller 416. The example switch 436 is shown as a single-pole, single-throw switch, but in practice, the switch 436 may be a FET with the control input being the gate of the FET. Thus, when the switch 436 is conductive, the source 320 is coupled between the lower terminal 104 and the lower base 204 (e.g., the active-on arrangement shown in FIG. 3C).

The example driver 108 further comprises the source 322 illustratively shown as a battery. The source 322 has a negative lead coupled to the lower terminal 104. Another electrically-controlled switch 440 (hereafter just switch 440) has a first lead coupled to the positive terminal of the source 322, a second lead coupled to the lower collector-emitter 208, and a control input coupled to the controller 416. The example switch 440 is shown as a single-pole, single-throw switch, but in practice, the switch 440 may be a FET with the control input being the gate of the FET. Thus, when the switches 432 and 440 are conductive, the source 322 is coupled between the lower base 204 and the lower collector-emitter 208 (e.g., the reverse recovery arrangement shown in FIG. 3E).

The controller 416 defines a control input 442, and control outputs 454, 456, 458, and 460 coupled to the control inputs of the switches 432, 436, and 440, and the lower cascode FET 210, respectively. When the control input 442 is asserted and the switch assembly 100 is forward biased, the controller 416 is designed and constructed to arrange the bipolar junction device 200 and cascode FET 210 for conduction from the upper terminal 102 to the lower terminal 104. When the control input 442 is de-asserted and the switch assembly 100 is still forward biased, the controller 416 is designed and constructed to interrupt current flow by making the cascode FET 210 non-conductive, and arranging the bipolar junction device 200 to block current flow from the upper terminal 102 to the lower terminal 104. Stated otherwise, the controller 416 is configured to selectively arrange for conduction of bipolar junction device 200 when the switch assembly is forward biased.

Oppositely, independent of the state of the control input 442, when the switch assembly 100 is reverse biased, the controller is designed and constructed to arrange bipolar junction device 200 for conduction from the lower terminal 104 to the upper terminal 102. In some cases, when the switch assembly 100 is reverse biased, the cascode FET 210 is made conductive, though such is not strictly required because of the body diode associated with the cascode FET 210. Stated otherwise, the controller 416 is configured to non-selectively arrange the bipolar junction device 200 for conduction when the switch assembly is reverse biased.

In order to make the switch assembly 100 selectively conductive during forward biased conditions, and non-selectively conductive during reverse biased conditions, the controller 416 senses the polarity of the applied voltage. Thus, the example controller 416 may further define a polarity input 462 that receives a Boolean indication of the applied polarity. In the example driver 108, a comparator 480 has a first input coupled to the upper terminal 102 (the connection shown by bubble “A”) and a second input coupled to the lower terminal 104. The comparator 480 defines a compare output coupled to the polarity input 462. While FIG. 4 shows the first and second inputs coupled directly to the respective terminals, in practice the voltage across the bipolar junction device 200 when non-conductive may be large (e.g., 1200V) and thus each of the first and second inputs may be coupled to their respective conduction terminals by way of respective voltage divider circuits. In yet still further cases, the applied polarity may be determined by systems and devices external to the switch assembly 100, and a Boolean signal sent across the electrical isolator 418 to the polarity input 462.

The controller 416 may be individual circuit components, an application specific integrated circuit (ASIC), a microcontroller with controlling software, a reduced-instruction-set computing (RISC), a digital signal processor (DSP), a processor with controlling software, a programmable logic device (PLD), a field programmable gate array (FPGA), a programmable system-on-a-chip (PSOC), and/or combinations, configured to read the control input 442, read the polarity input 462, and drive control outputs to implement the mode transitions of the bipolar junction device 200.

In example systems, the switch assembly 100 is electrically floated. In order to receive the control input 442 in the electrical domain of the switch assembly 100, the example driver 108 implements the electrical isolator 418. The example electrical isolator 418 may take any suitable form, such as optocouplers or capacitive isolation devices. Regardless of the precise nature of the electrical isolator 418, external control signals (e.g., Boolean signals) may be coupled to the control input 464 of the electrical isolator 418, and control input 464 may be the control terminal 106 illustratively presented in FIG. 1. The electrical isolator 418, in turn, passes the control signals through to the electrical domain of the switch assembly 100. In the example, the external control signal is passed through to become the control input 442 of the controller 416.

Turning now to the isolation transformer 420. Various devices within the switch assembly 100 may use operational power. For example, the controller 416 may use a bus voltage and power to enable implementation of the various modes of operation of the bipolar junction device 200. Further, the sources within system may be implemented as voltage sources in the form of switching power converters, or current sources also in the form of switching power converters. The switching power converters implementing the sources may use bus voltage and power. In order to provide operational power within the electrical domain of the switch assembly 100, the isolation transformer 420 is provided. External systems (not specifically shown) may provide an alternating current (AC) signal across the primary leads 468 and 470 of the isolation transformer 420 (e.g., 15V AC). The isolation transformer 420 creates an AC voltage on the secondary leads 472 and 474. The AC voltage on the secondary of the isolation transformer 420 may be provided to an AC-DC power converter 476, which rectifies the AC voltage and provides power by way of bus voltage V_{BUS} (e.g., 3.3V, 5V, 12V) with respect to a reference voltage or common 478. The power provided by the AC-DC power converter 476 may be used by the various components of the switch assembly 100. In other cases, multiple isolation transformers may be present (e.g., one for each side of the bipolar junction device). Further still, a single isolation transformer with multiple secondary windings may be used. The discussion now turns to example arrangements for making the bipolar junction device 200 conductive and/or non-conductive in the context of the switch assembly 100.

Consider, as an example, a situation in which the switch assembly 100 is forward biased. Further consider that the control input 464 of the electrical isolator 418 is de-asserted, and thus the control input 442 of the controller 416 is de-asserted. Based on the de-asserted state of the control input 442, the controller 416 is designed and constructed to place the bipolar junction device 200 in the non-conductive arrangement taking into account the applied polarity (e.g., as read by the controller 416 through the polarity input 462). Thus, under the assumptions, the cascode FET 210 is non-conductive and the switch 432 is conductive, implementing passive-off (FIG. 3A).

Still considering the example forward biased condition, now consider that the control input 464 of the electrical isolator 418 is asserted, and thus the control input 442 of the controller 416 is asserted. Based on the assertion, the controller 416 is designed and constructed to place the bipolar junction device 200 in the active-on arrangement (FIG. 3C). To that end, the controller 416 may assert the control output 460 to make the cascode FET 210 conductive, assert the control output 456 to make the switch 436 conductive, and de-assert or leave de-asserted the remaining control outputs.

Optionally, again in the forward biased condition, the controller 416 may be designed and constructed to take the bipolar junction device 200 through an intermediate conductive arrangement before arriving at the active-on arrangement. For example, the controller 416 may momentarily place the bipolar junction device 200 in the passive-on arrangement (FIG. 3B). When used, the passive-on arrangement may last a predetermined period (e.g., from about 0.1 μs to 5 μs).

Still referring to FIG. 4, and still considering the forward biased condition, further consider that the control input 464 of the electrical isolator 418 transitions from asserted to de-asserted, and thus the control input 442 of the controller 416 transitions from asserted to de-asserted. Based on the transition, the controller 416 may be designed and constructed to place the bipolar junction device 200 into the reverse recovery arrangement (FIG. 3E). To that end, the controller 416 de-asserts the control output 460 to make the cascode FET 210 non-conductive to interrupt the main load current through the bipolar junction device 200, asserts the control output 454 to make the switch 432 conductive to couple the lower base 204 to the lower terminal 104, and assert the control output 458 to make the switch 440 conductive to couple the source 322 between the lower base 204 and the lower collector-emitter 208. As previously mentioned, the reverse recovery arrangement may be implemented for a predetermined period of time, in some cases about 400 nanoseconds. Thereafter, the controller 416 may transition the bipolar junction device 200 to the passive-off arrangement (FIG. 3A).

Now consider a situation in which the switch assembly 100 is reverse biased. As previously discussed, the example switch assembly 100 non-selectively conducts reverse current during periods of reverse bias. Thus, the state of the control input 442 is a “don't care” condition—the switch assembly 100 conducts regardless of the state of the control input 464. Based on the reverse biased condition, the controller 416 is designed and constructed to place the bipolar junction device 200 in a conductive arrangement. To that end, the controller 416 may: 1) de-assert all the control outputs, thus enabling the reverse current to flow through the body diode of the cascode FET 210; 2) assert the control output 460 to make the cascode FET conductive, and de-assert or leave de-asserted the remaining control outputs (FIG. 3F); 3) assert the control output 454 to make the switch 432 conductive, assert the control output 460 to make the cascode FET conductive, and de-assert or leave de-asserted the remaining control outputs (FIG. 3G); or 4) assert the control output 456 to make the switch 436 conductive, assert the control output 460 to make the cascode FET conductive, and de-assert or leave de-asserted the remaining control outputs (FIG. 3H). In some cases, the controller 416 may transition through two or more of these states, such as state 1) follows by state 2) or state 3) or state 4).

Referring again briefly to FIG. 3A. The example bipolar junction device 200 is shown as monolithic structure. That is, the upper collector-emitter 206 is associated with or proximate to an upper portion of the drift region. Similarly, the lower base 204 and lower collector-emitter 208 are associated with or proximate to a lower portion of the drift region. The example drift region is a continuous structure. The example bipolar junction device 200 may be manufactured by creating the upper collector-emitter 206 on an upper side of a wafer. The wafer may then be flipped and bonded to a handle wafer, and thereafter the lower base 204 and lower collector-emitter 208 are created on the second side of the wafer. The manufacturing steps may also be reversed, creating the lower base 204 and lower collector-emitter 208 first, and then flipping and creating the upper collector-emitter 206. Having a continuous drift region may mean that, for positive polarity on the upper terminal 102, charge carrier injection by way of the upper P-type region 310 (e.g., FIG. 3B or 3D) drops the Vceon sufficiently that charge carrier injection from both sides (e.g., FIG. 3C) provides only an incremental benefit. However, in other cases the bipolar junction devices may be created with non-continuous drift regions.

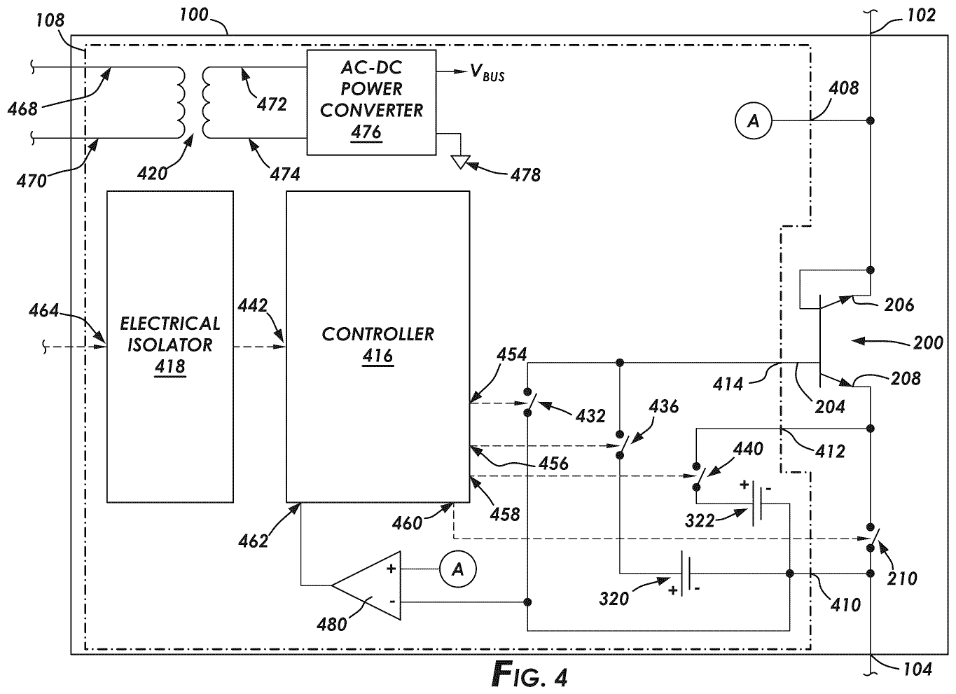

FIG. 5 shows, in shorthand form, a partial cross-sectional view of an example bipolar junction device of modular construction. In particular, the example bipolar junction device 200 of FIG. 5 comprises an upper component 500 and a lower component 502. The upper component 500 defines the upper collector-emitter 206 and an upper drift region 504. The upper component 500 further defines an internal P-type region 506 and internal N-type region 508 (e.g., N+), opposite the upper P-type region 310 and upper N-type region 330. The example bipolar junction device 200 further comprises the lower component 502. The lower component 502 defines the lower base 204, the lower collector-emitter 208, and a lower drift region 510. The lower component 502 further defines an internal P-type region 512 and internal N-type region 514, opposite the lower P-type regions 306 and lower N-type region 302.

The upper component 500 and the lower component 502 may be constructed on the same wafer or different wafers. After singulation of the upper component 500 and the lower component 502, the bipolar junction device 200 of FIG. 5 may be assembled by bonding the “backsides” of the upper component 500 to the lower component 502. Stated otherwise, the bipolar junction device 200 of FIG. 5 may be assembled by bonding the drift regions 504 and 510 of the upper component 500 and lower component 502, respectively. The bonding may involve use of a metallic material (e.g., solder, aluminum) to electrically and mechanically couple the upper drift region 504 to the lower drift region 510. In the example of FIG. 5, metallic material 516 bonds the P-type regions 506 and 512, and metallic material 518 bonds the N-type regions 508 and 514. Co-pending and commonly assigned U.S. application Ser. No. 18/422,469 (hereafter the '469 Application) filed Jan. 25, 2024 titled “Methods and Systems of Operating a Double-Sided Double-Base Bipolar Junction Transistor” describes construction of a two-component arrangement with internal P-type and N-type regions, and the '469 Application is incorporated by reference herein as if reproduced in full below.

The amount a wafer can be thinned, such as by backside grind, is dependent upon the diameter of the wafer. Smaller diameter wafers may be thinned more than larger diameter wafers. For example, a six-inch diameter wafer, which may have an initial thickness of about 500 microns, may be thinned to about 75 or 80 microns without significant warpage. However, larger diameter wafers, such as eight- or twelve-inch diameter wafers, are thicker (e.g., 750 microns) to provide structural stability for the wafer itself. Thinning a larger diameter wafer is not practical in most situations, as the larger diameter wafers tend to warp significantly when thinned. Stated otherwise, the monolithic bipolar junction device 200 of FIGS. 3A-3H, and the upper/lower components of the modular bipolar junction device 200 of FIG. 5, may be constructed on six-inch wafers; however, construction of the either the monolithic or modular version may not be practical on larger diameter wafers (e.g., eight inch, twelve inch) because of limitations on thinning caused by warpage. The specification now turns to another modular bipolar junction device 200 that may nevertheless be constructed on the larger diameter wafers.

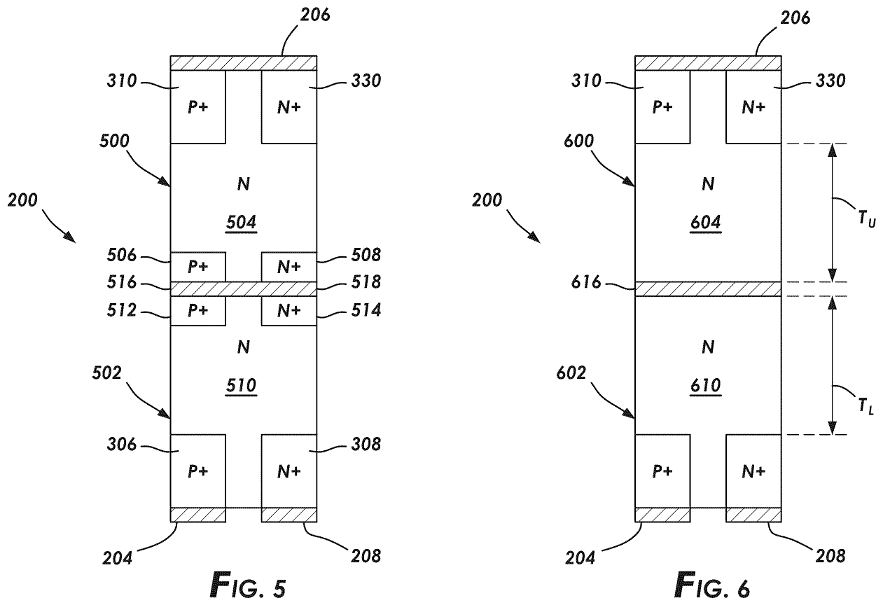

FIG. 6 shows, in shorthand form, a partial cross-sectional view of an example bipolar junction device of modular construction. In particular, the bipolar junction device 200 of FIG. 6 comprises an upper component 600 and a lower component 602. The upper component 600 defines the upper collector-emitter 206 and an upper drift region 604. The example upper component 600 omits the internal P-type and N-type regions on the “backside” shown in the embodiment of FIG. 5. The example bipolar junction device 200 further comprises the lower component 602. The lower component 602 defines the lower base 204, the lower collector-emitter 208, and a lower drift region 610. The lower component 602 omits the internal P-type and N-type regions on the “backside” shown in the embodiment of FIG. 5.

The upper component 600 and the lower component 602 may be constructed on the same wafer or different wafers. After singulation of the upper component 600 and the lower component 602, the bipolar junction device 200 of FIG. 6 may be assembled by bonding the “backsides” of the upper component 600 to the lower component 602. Stated otherwise, the bipolar junction device 200 of FIG. 6 may be created by bonding the drift regions 604 and 610 of the upper component 600 and lower component 602, respectively. The bonding may involve use of a metallic material (e.g., solder, aluminum) to electrically and mechanically couple the upper drift region 604 to the lower drift region 610. In the example of FIG. 6, the metallic material 616 bonds the N-type drift regions 604 and 610. Stated otherwise, the metallic material 616 mechanically and electrically couples the N-type drift regions 604 and 610. In order to reduce or avoid creation of a Schottky barrier at the metal/silicon interface, in some examples thin N-type doping (e.g., N+) may be present on the “backsides” of each component 600 and 602 adjacent to the metallic material 616, though the doping to reduce or avoid the Schottky barriers is not expressly shown. Again, co-pending and commonly assigned '469 Application noted above describes a two-component arrangement without internal P-type and N-type regions.

Still referring to FIG. 6. When the example bipolar junction device 200 of FIG. 6 is forward biased and in the passive-off arrangement (FIG. 3A), a depletion region forms within the lower drift region 610 extending upward from the lower base 204. However, the depletion region formed in association with the lower base 204 may not “cross” the bonding into the upper drift region 604. That is to say, the metallic material 616 can be thought of as an infinite supply of electrons, and thus the depletion region formed starting at the lower base 204 cannot extend through the metallic material 616 into the upper drift region 504 because of the absence of the internal P-type regions, such as in FIG. 5. It follows, the amount of voltage/current blocking provided by the bipolar junction device 200 of FIG. 6 is directly related to the individual thickness T of each of the drift regions 604 and 610. For example, for a thickness TL of the lower drift region 610 of about 150 to 160 microns, the bipolar junction device 200 of FIG. 6 may block about 1200V. Inasmuch as the example bipolar junction device 200 is not used to the block voltage/current during reverse biased conditions, the thickness Tu of the upper drift region 604 need not be as thick; however, when the upper and lower components 600 and 602 are created on larger diameter wafers, the thickness Tu may similarly be about 150 to 160 microns.

In the various example bipolar junction devices 200 discussed to this point, the lower base and lower collector-emitter include doped regions that intersect the lower surface of the substrate 300. Similarly, the upper P-type region 310 associated with the upper collector-emitter 206 likewise intersects the upper surface of the substrate 300. However, in other cases, the upper P-type region 310, the lower P-type region 306, and/or the lower N-type region may be created by trench-tip doping such that the regions do not interested their respective surfaces.

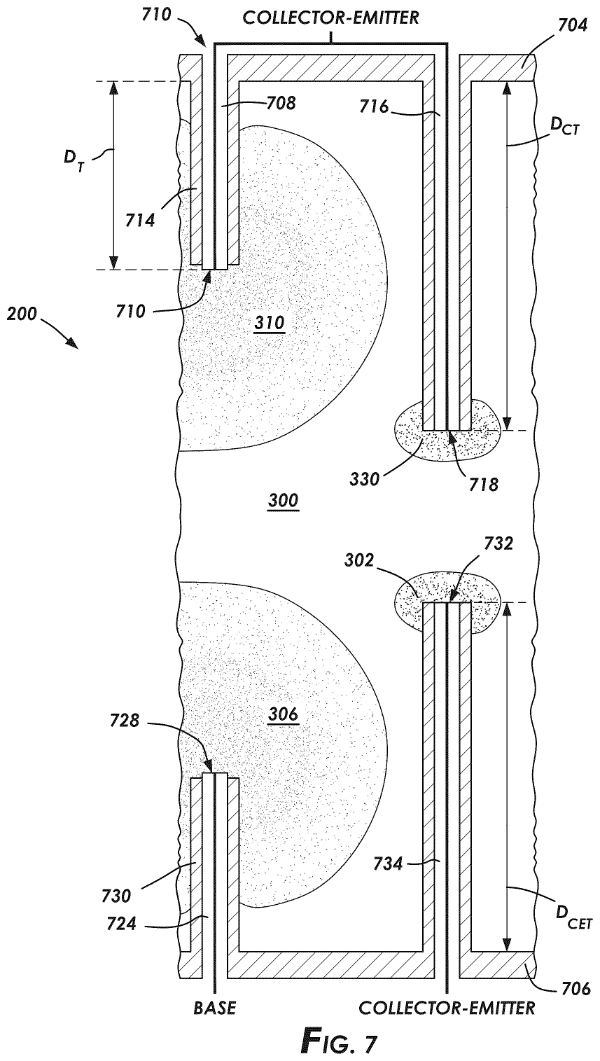

FIG. 7 shows a cross-sectional view of a portion of a bipolar junction device 200 in accordance some embodiments. In particular, FIG. 7 shows a partial cross-sectional view of the bipolar junction device 200 comprising the substrate 300 having an upper face or upper side 704 and a lower face or lower side 706. As before, the designations “upper” and “lower” are arbitrary and used merely for convenience of the discussion. The upper side 704 faces a direction opposite the lower side 706. Stated differently, an outward pointing vector normal to the average elevation of the upper side 704 (the vector not specifically shown) points an opposite direction with respect to an outward pointing vector normal to the average elevation of the lower side 706 (the vector not specifically shown).

The upper side 704 includes an upper trench 708. The example upper trench 708 defines an open end or proximal opening and a bottom or distal end 710 disposed within the substrate 300. The upper trench 708 may be created within the substrate using any suitable technique, such as plasma etching. The upper trench 708 defines a depth DT measured from the upper side 704 to the distal end 710. Moreover, the upper trench 708 defines width measured perpendicular to the depth DT. In example cases, the ratio of the depth of a trench to the width of the trench may be 5:1 or less (e.g., 4:1, 2:1). For a device voltage rating of between about 600V and 1200V, and a wafer thickness of 250 microns, the example upper trench 708 may have a depth Dr of between and including 10 and 50 microns, and thus may have a width of at least 2 microns to at least 10 microns, respectively. For a device voltage rating of between about 600V and 1200V, and a wafer thickness of 300 microns, the example trench 708 may have a depth DT of between and including 35 and 75 microns, and thus may have a width of at least 6 microns to at least 15 microns, respectively.

The example upper trench 708 is associated with an oxide layer 714. In particular, as part of the manufacturing process, an oxide layer 714 is grown or otherwise created at least on the sidewalls of the example upper trench 708. The example oxide layer 714 may serve several purposes. The oxide layer 714 may act as a barrier during creation of the upper P-type region 310. Further, the oxide layer 714 may act to electrically insulate an electrical connection (e.g., metal, shown only schematically) associated with the upper P-type region 310 from the doped and un-doped semiconductor material around the upper trench 708.

The upper P-type region 310 may be created by placing dopant material through the distal end 710 of the upper trench 708. That is, for example, rather than the dopant impinging on the upper side 704 during implant, the dopant travels along the upper trench 708 and impinges on the semiconductor material exposed at the distal end 710 of the upper trench 708. Such implantation may be referred to as trench-tip doping or trench-tip implantation. The result of trench-tip doping and the diffusion depth is that the upper P-type region resides below the upper side 704 and deeper within the substrate 300 compared to implantation by having the dopant impinge directly on the upper side 704. Stated otherwise, in one example the dopant that forms the upper P-type region 310 does not intersect or reside at the upper side 704.

Still referring to FIG. 7, the upper side 704 further includes an upper contact trench 716. The example upper contact trench 716 defines an open end or proximal opening and a bottom or distal end 718 disposed within the substrate 300. The upper contact trench 716 may be created within the substrate using any suitable technique, such as plasma etching. The upper contact trench 716 defines a depth D_{CT} measured from the upper side 704 to the distal end 718. Moreover, the upper contact trench 716 defines width measured perpendicular to the depth D_{CT}. In example cases, the ratio of the depth of a trench to the width of the trench may be 5:1 or less (e.g., 4:1, 2:1). In some example cases, the example upper contact trench 716 may have a depth D_{CT} greater than the depth DT of the upper trench 708, and as shown in FIG. 7.

The example upper contact trench 716 is also associated with the oxide layer 714. As before, the example oxide layer 714 may serve several purposes. The oxide layer 714 may act as a barrier during creation of the ohmic contact between an electrical connection (e.g., metal, shown only in schematic form) and the substrate 300. Further, the oxide layer 714 may act to electrically insulate the electrical connection to the substrate 300 from the semiconductor material around the upper contact trench 716.

The ohmic contact to the substrate may be created by placing the upper N-type region 330 by way of the distal end 718 of the upper contact trench 716. That is, for example, rather than the upper N-type region 330 impinging on the upper side 704, during construction the dopant and/or metal travels along the upper trench 708 and impinges on the semiconductor material exposed at the distal end 718 of the upper contact trench 716. Regardless, the result is that the upper N-type region 330 resides below the upper side 704 and deeper within the substrate 300 than a majority of the P-type region 310 associated with the upper trench 708. Stated otherwise, in this example, any doping and/or material used to create an ohmic connection to the substrate 300 do not intersect or reside at the upper side 704.

The example lower side 706 includes a lower base trench 724. The example lower base trench 724 defines an open end or proximal opening and a bottom or distal end 728 disposed within the substrate 300. The lower base trench 724 defines a depth measured from the lower side 706 to the distal end 728 (though the depth is not specifically delineated in FIG. 7), and lower base trench 724 defines a width. As with the upper trenches, the ratio of the depth of the lower base trench 724 to the width may be 5:1 or less (e.g., 4:1, 2:1). The example lower base trench 724 may have a depth of between and including 10 and 50 microns, and thus may have a width of at least 2 microns to at least 10 microns, respectively.

Still referring to FIG. 7, the example lower base trench 724 is associated with an oxide layer 730. In particular, as part of the manufacturing process, the oxide layer 730 is grown or otherwise created at least on the sidewalls of the example lower base trench 724. In practice, the oxide layer 730 may initially cover all surfaces of the lower side 706, but then may be etched (e.g., plasma etch, wet etch) to create various openings, such as an opening at the distal end 728 of the lower base trench 724, and the opening at the distal end 732 to expose a lower collector-emitter region, discussed more below. As before, the example oxide layer 730 may serve several purposes. The oxide layer 730 may act as a barrier during creation of the lower P-type region 306. Further, the oxide layer 730 may act to electrically insulate the electrical connection (e.g., metal, shown schematically) associated with the lower P-type region 306 from the semiconductor material around the lower-base trench 724.

The example bipolar junction device comprises the lower P-type region 306 associated with the lower side 706, and which forms a junction with the substrate 300. In example cases, the lower P-type region 306 is created by placing a dopant material through the distal end 728 of a lower base trench 724. The result of the trench-tip doping and the diffusion depth is that the lower P-type region 302 resides deep within the substrate 300 compared to implanting by having the dopant impinge directly on the lower side 706. Stated otherwise, in one example the dopant that forms the lower P-type region 306 does not intersect or reside at the lower side 706.

Still referring to FIG. 7, the lower side 706 further includes a lower-CE trench 734. The example lower-CE trench 734 defines an open end or proximal opening and a bottom or distal end 732 disposed within the substrate 300. The lower-CE trench 734 may be created within the substrate using any suitable technique, such as plasma etching. The lower-CE trench 734 defines a depth D_{CET} measured from the lower side 706 to the distal end 732. Moreover, the lower-CE trench 734 defines width measured perpendicular to the depth D_{CET}. In example cases, the ratio of the depth of a trench to the width of the trench may be 5:1 or less (e.g., 4:1, 2:1). In some example cases, the example lower-CE trench 734 may have a depth D_{CET} greater than the depth of the lower base trench 724.

The example lower-CE trench 734 is also associated with the oxide layer 730. As before, the example oxide layer 730 may serve several purposes. The oxide layer 730 may act as a barrier during creation of the lower N-type region 302. Further, the oxide layer 730 may act to electrically insulate an electrical connection (e.g., metal, shown schematically) to the lower N-type region 302. The lower side 706 is further associated the lower N-type region 302. In the example of FIG. 7, the lower N-type region 302 is created by the dopant impinging on the substrate 300 through the lower-CE trench 734, again trench-tip doping. Based the depths of the various trenches associated with the lower side 706, the lower N-type region 302 may be deeper within the substrate 300 than the lower P-type region 306.

The creation of the various N-type and P-type regions is described in greater detail in commonly assigned U.S. Pat. No. 11,881,525, issued 23 Jan. 2024, titled “Semiconductor Device with Bi-Directional Double-Base Trench Power Switches”, incorporated by reference herein as if reproduced in full below. The '525 Patent, however, does not contemplate the metallic layer coupling of the upper P-type region 310 and the upper N-type region 330. Moreover, the naming convention of the various regions of the device in the '525 Patent is based on the internal device physics of the BJ T; by contrast, the naming convention in this specification is based on the path carrying the majority of the main load current. It follows, to the extent the naming conventions as between the '525 Patent and this specification contradict each other, for purposes of this specification and claims the naming convention herein supersedes and controls.

Finally with respect to FIG. 7, the trenches 708, 716, 724, and 734 are shown as part of a single device. However, other example devices may have some doped regions created through trenches, and other doped regions created at the respective surfaces. In one example, the upper P-type region 310 may be created such that the P-type region intersects the upper side 704, while all the other contacts and regions are disposed at the distal ends of respective trenches. As another example, the upper P-type region 310 and the upper ohmic contact to the substrate 300 may be created to intersect the upper side 704, while all the lower regions are disposed at distal ends of respective trenches. Similarly, the lower P-type region 306 may be created such that the P-type region intersects the lower side 706, while all the other contacts and regions are disposed at the distal ends of respective trenches. As another example, the lower P-type region 306 and the lower N-type region 302 may be created to intersect the lower side 706, while all the upper regions are disposed at distal ends of respective trenches.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s). Moreover, this paragraph shall not negate that a base electrically connected to a collector-emitter through a transistor may be referred to as “directly coupled.”

The above discussion is meant to be illustrative of the principles and various embodiments of the present invention. Numerous variations and modifications will become apparent to those skilled in the art once the above disclosure is fully appreciated. For example, the cascode FET 210 is shown to be part of the switch 110, while other FETs are shown to be part of the driver 108 for logical consistency; however, the cascode(s) may be implemented as part of driver without departing from the contemplation of this disclosure. It is intended that the following claims be interpreted to embrace all such variations and modifications.

What is claimed is:

1. A bipolar junction device, comprising:
a lower collector-emitter defined by a lower N-type region disposed within a substrate of N-type material;
a lower base defined by a lower P-type region disposed within the substrate; and
an upper collector-emitter comprising:
an upper P-type region disposed within the substrate; and
a metal layer disposed on an upper surface of the substrate, a first portion of the metal layer electrically coupled to the upper P-type region, and a second portion of the metal layer electrically coupled to the substrate, the second portion displaced from the first portion.

2. The bipolar junction device of claim 1, wherein the second portion of the metal layer is in ohmic contact with the substrate.

3. The bipolar junction device of claim 1, wherein the first portion of the metal layer is in ohmic contact with the upper P-type region.

4. The bipolar junction device of claim 1, wherein the upper P-type region intersects the upper surface.

5. The bipolar junction device of claim 1, wherein the upper P-type region does not intersect the upper surface.

6. The bipolar junction device of claim 1, further comprising an upper N-type region electrically disposed between the second portion of the metal layer and the substrate, wherein the upper N-type region intersects the upper surface.

7. The bipolar junction device of claim 1, further comprising an upper N-type region electrically disposed between the second portion of the metal layer and the substrate, wherein the upper N-type region does not intersect the upper surface.

8. The bipolar junction device of claim 1, wherein the lower P-type region intersects a lower surface of the substrate.

9. The bipolar junction device of claim 1, wherein the lower P-type region does not intersect a lower surface of the substrate.

10. The bipolar junction device of claim 1, wherein the lower N-type region intersects a lower surface of the substrate.

11. The bipolar junction device of claim 1, wherein the lower N-type region does not intersect a lower surface of the substrate.

12. The bipolar junction device of claim 1 further comprising:
an upper component that defines the upper P-type region and a backside; and
a lower component that defines the lower P-type region, the lower N-type region, and a backside,
wherein the backsides of the upper component and the lower component are bonded together.

13. A switch assembly comprising:
an upper terminal, a lower terminal, and a control terminal;
a cascode FET defining a drain, a source coupled to the lower terminal, and a gate;
a driver coupled to the gate of the cascode FET; and
a bipolar junction device comprising:
a lower collector-emitter defined by a lower N-type region disposed within a substrate of N-type material, the lower collector-emitter coupled to the drain of the cascode FET;
a lower base defined by a lower P-type region disposed within the substrate; and
an upper collector-emitter coupled to the upper terminal, the upper collector-emitter comprising:
an upper P-type region disposed within the substrate; and
a metal layer disposed on an upper surface of the substrate, a first portion of the metal layer electrically coupled to the upper P-type region, and a second portion of the metal layer electrically coupled to the substrate, the second portion displaced from the first portion;
wherein the driver is configured to:
during periods of time when the switch assembly is forward biased and the control terminal is asserted, arrange the bipolar junction device to conduct a forward current from the upper terminal, through the upper collector-emitter, and to the lower terminal;
during periods of time when the switch assembly is forward biased and the control terminal is de-asserted, arrange the bipolar junction device to block current from the upper terminal to the lower terminal; and
during periods of time when the switch assembly is reversed biased, arrange the bipolar junction device to non-selectively conduct a reverse current from the lower terminal, to the lower collector-emitter, and to the upper terminal.

14. The switch assembly of claim 13:
the driver further comprising a lower FET defining a drain coupled to the lower base, a source coupled to the lower terminal, and a gate coupled to the driver;
the driver is configured to, during periods of time when the switch assembly is forward biased and the control terminal is de-asserted:
couple the lower base to the lower terminal by way of the lower FET; and
make the cascode FET non-conductive.

15. The switch assembly of claim 13:
further comprising a source defining a positive terminal and a negative terminal; and
the driver is configured to, during periods of time when the switch assembly is forward biased and the control terminal is asserted:
couple the positive terminal of the source to the lower base and couple the negative terminal to the lower terminal of the switch assembly; and
make the cascode FET conductive.

16. The switch assembly of claim 13:
the driver further comprising a source defining a positive terminal and a negative terminal; and
the driver is configured to, during at least portions of periods of time when the switch assembly is forward biased and the control terminal is de-asserted:
couple the positive terminal of the source to the lower collector-emitter and couple the negative terminal to the lower base; and
make the cascode FET non-conductive.

17. The switch assembly of claim 13 wherein the driver is further configured to, during at least portions of periods of time when the switch assembly is reversed biased, make the cascode FET conductive.

18. The switch assembly of claim 17, wherein:
the driver further comprises a lower FET defining a drain coupled to the lower base, a source coupled to the lower terminal, and a gate coupled to the driver; and
the driver is further configured to, during at least portions of periods of time when the switch assembly is reversed biased, make the cascode FET conductive.
